(19) United States
(12) Patent Application Publication
(10) Pub. No.: US 2025/0204057 A1
(43) Pub. Date: Jun. 19, 2025

(54) PHOTOVOLAIC MODULE WITH AN ALTERNATIVE ELECTRICALLY INSULATIVE BACK SHEET AND METHOD OF MAKING THE SAME

(71) Applicant: TOLEDO SOLAR INC., Perrysburg, OH (US)

(72) Inventors: Mark HARTEL, Avon, OH (US); Aaron BATES, Elyria, OH (US)

(21) Appl. No.: 18/852,733

(22) PCT Filed: Mar. 28, 2023
(86) PCT No.: PCT/US2023/016580

§ 371 Date: Sep. 30, 2024

Related U.S. Application Data
(60) Provisional application No. 63/324,349, filed on Mar. 28, 2022.

(51) Int. Cl. H10F 19/85; H10F 19/31; H10F 19/80

(52) U.S. Cl. CPC H10F 19/85; H10F 19/31; H10F 19/807

(57) ABSTRACT

A thin film photovoltaic module includes a submodule with a first glass layer, a transparent conducting oxide layer, a thin film semiconductor layer, and a conductive back contact layer. The thin film module may further include a lamination layer and an electrically insulative backing layer. In one embodiment, the module may include a clip-less mounting feature comprising at least a first and second hole formed in the electrically insulative backing layer.

### RELATED APPLICATIONS

This application claims priority to U.S. Provisional Application No. 63/324,349, filed Mar. 28, 2022, which is incorporated herein in its entirety.

### GOVERNMENT LICENSE RIGHTS

This invention was made with government support under Grant Award No. DE-SC0020805 awarded by the U.S. Department of Energy. The government has certain rights in the invention.

### RELATED TECHNOLOGY

This application relates to photovoltaic modules for use in building integrated photovoltaics (BIPV), such as high-efficiency photovoltaic facades, building spandrels, and rooftop modules, including but not limited, to rooftop shingles.

### BACKGROUND

As the demand for energy efficient products increase, so does the demand for energy-efficient materials that can be incorporated into the envelope of newly constructed buildings. Historically, photovoltaics (PV) have been used to create thin film cadmium telluride (CdTe) energy panels that can be used to form arrays capable of being connected to the electrical grid.

Today, CdTe technology powers 40% of the (U.S.) domestic utility-scale PV solar market and is expected to reach 60% in the next several years. CdTe Solar PV modules have proven themselves over the last several decades as the most robust, powerful, longest lasting solar technology in the world.

Glass-to-glass laminated CdTe PV modules have been established as the most competitive technology among thin film photovoltaics due to high performance, lowest cost, and high reliability. Unfortunately, overall weight of the glass-to-glass modules is governed by the thickness of the two glass sheets used for module fabrication that may restrict potential installation projects due to roof loading restrictions. Roof-top PV installation is labor intensive, involving lifting PV modules to the roof, attaching individual mounting clips to the modules, and attaching the modules to roof-top frame structures. It would be beneficial to reduce the weight of the existing CdTe PV modules for rooftop and other applications and reduce the time needed for module installation through an integrated mounting feature, as part of the module, without the need for additional mounting clamps or clips.

### SUMMARY

In one embodiment, a thin film photovoltaic module includes a submodule comprising a first glass layer, a transparent conducting oxide layer, a thin film semiconductor layer, and a conductive back contact layer. The module may also include a lamination layer, which may include a polyolefin material, and an electrically insulative backing layer. In one embodiment, the electrically insulative backing layer may be enameled steel, a polymer material, a ceramic material, or a combination thereof.

In another embodiment, the electrically insulative backing layer may be a steel core having a first side and a second side, wherein the first and second sides are coated with a glass powder enamel material. The glass powder enamel material may be at least about 0.15 mm thick on each of the first and second sides of the steel core. In another embodiment, the thin film semiconductor layer may be cadmium telluride, copper indium gallium selenium, amorphous silicon, perovskites, or combinations thereof and may be no more than 10,000 nm thick.

In one embodiment, the electrically insulative backing layer may include a clip-less mounting feature defined by at least a first hole and second hole formed through the electrically insulative backing layer.

In another embodiment, a method of making a thin film photovoltaic module includes providing a submodule comprising a first glass layer, a transparent conducting oxide layer, a thin film semiconductor layer, and a metal back contact layer; and applying a lamination layer and an electrically insulative backing layer on top of the conductive back contact layer. The electrically insulative backing layer may be enameled steel, polymer material, ceramic material, or a combination thereof. The application of the lamination layer and the electrically insulative backing layer to the submodule may include a two-step pressing process and may further include forming at least a first and second mounting hole within the electrically insulative backing layer.

In one embodiment, the electrically insulative backing layer includes a steel core having a first side and a second side, and wherein the first and second sides are coated with a glass powder enamel material, wherein the glass powder enamel material is applied to each of the first and second sides of the steel core in a layer having a thickness of at least about 0.15 mm.

In another embodiment, the thin film semiconductor layer may be made of cadmium telluride, copper indium gallium selenium, amorphous silicon, perovskites, or combinations thereof and may be no more than 10,000 nm thick.

### BRIEF DESCRIPTION OF THE DRAWINGS

FIG. 1 is a side cross-sectional view of a thin film PV module including an alternative electrically insulative backsheet.

FIG. 2 is a schematic cross-sectional representation of a thin film steel-backed PV module:

FIG. 3 is a side cross-sectional view of a submodule of a thin film electrically insulative backed PV module:

FIG. 4 is a graphical representation of the results of a Press and Re-press lamination process used to combine (laminate) the submodule with an enameled steel backsheet.

FIG. 5 is a front perspective (plan) view of an embodiment of a PV with an enameled steel backsheet including clip-less integral mounting feature(s).

### DETAILED DESCRIPTION

An alternatively backed, thin film photovoltaic module 10 for use as high efficiency solar rooftop modules, building facades, and rooftop materials, and the like, is provided. It should be understood that a thin film photovoltaic module is generally understood to be a module that uses a thin film of semiconductor as part of its electrical generation from sunlight. Thin film is defined as an PV semiconductor that is equal to or less than 10.000 nm in thickness. Examples of such thin film semiconductors include, but are not limited to, CdTe. Copper Indium Gallium Selenium (CIGS), Amorphous Silicon (a-Si), and Perovskites. Thin film PV modules typically require the semiconductor to be encapsulated within the module using an electrically insulative back plate.

Back plates for PV modules are generally glass. However, for the thin film PV modules 10, an alternative, electrically insulative, material is used as a back sheet to encapsulate the semiconductor. Examples of this alternative material may include, but are not limited to enamel coated metals, such as steel, polymer sheets, and ceramic sheets. It should also be understood that any suitable electrically insulative material can be used. Suitable electrically insulative materials for the thin film PV module 10 are those capable of passing International Electrotechnical Commission (IEC) and Underwriters Laboratory (UL) 61215-1 testing standards for PV module safety, including the insulation test (MQT 3) and the wet leakage current test (MQT 15). For the purpose of this application, the back plate will be referred to as an enameled steel backing or back sheet.

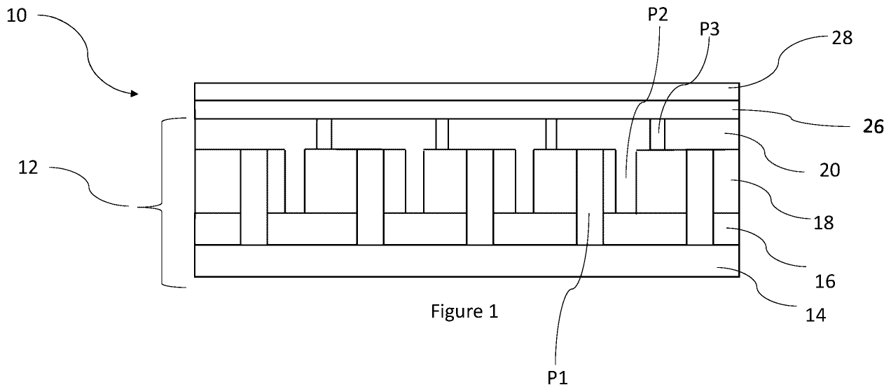

As shown in FIG. 1, the enameled steel-backed thin film PV module 10 may be used as an aesthetically pleasing alternative to traditional facade or roofing materials. It has been found that by using an enameled steel backsheet 28 instead of a traditional glass backsheet, the overall weight of the PV may be reduced by as much as 27%. In addition, the enameled steel backsheet 28 may be preformed to incorporate mounting features for the PV module, eliminating the need for additional clamps or mounting hardware.

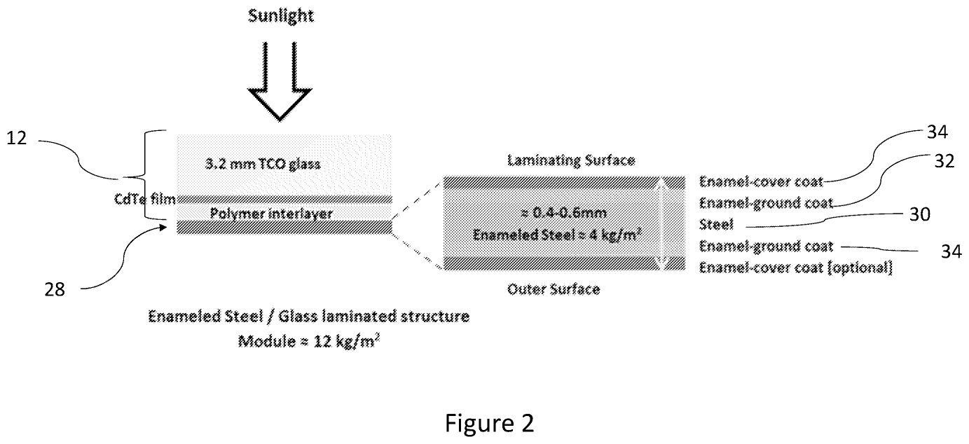

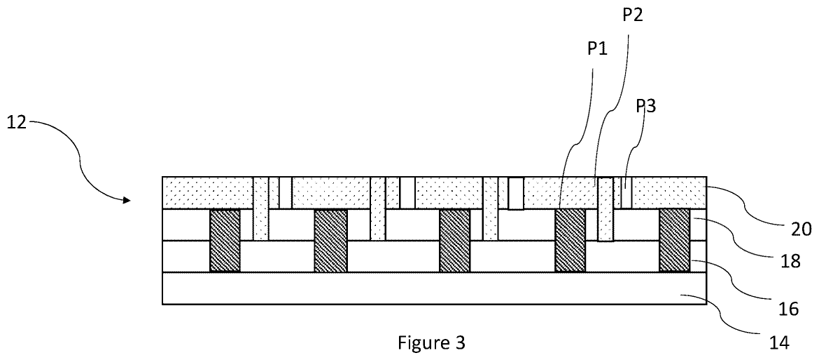

As shown in FIGS. 1, 2, and 3, the enameled steel-backed thin film PV module 10 is created by first constructing an opaque thin film submodule 12 and then combining it with an interlayer 26 and an enameled steel backsheet 28 (See FIGS. 1 and 2). As shown in FIG. 3, the opaque thin film CdTe submodule 12 may be created using any known suitable technique, such as the one disclosed in U.S. Pat. No. 9,337,069, which is incorporated herein by reference.

Referring now to 3, in one embodiment the opaque thin film submodule 12 includes a soda-lime silicate or other transparent glass layer 14, a transparent conducting oxide layer 16, a CdTe (or CdSeTe) layer or other photovoltaically-active thin film semiconductor layer 18, and a metal back contact layer or alternative conductive back contact layer 20. In one embodiment, the glass layer 14 may be pre-coated with the transparent conducting oxide layer (TCO) 16 that includes a buffer layer of undoped tin oxide (SnO₂) or other suitable resistive buffer layer. The CdTe layer 18 may then be deposited on top of the TCO layer 16 using any known deposition process. In one embodiment, the CdTe layer 18 is deposited on the TCO layer 16 using a vertical vapor transport deposition (VVTD) process, such as the one disclosed in U.S. Pat. No. 9,337,069, to form a CdTe coated glass substrate. In one embodiment, the CdTe layer 18 includes a cadmium sulfide layer that is about 50 nm to about 200 nm thick and a cadmium telluride layer that is about 2000 nm to about 4000 nm thick. In another embodiment the cadmium sulfide layer is about 100 to about 200 nm thick, and the cadmium telluride layer is about 2000 to about 4000 nm thick.

In yet another embodiment, the CdTe layer includes a CdSeTe layer about 100 to 200 nm thick and a CdTe layer 2000 nm to 4000 nm thick. The CdSeTe layer may have a gradient of Se ranging from about 40% near the TCO to 0% where it merges with the CdTe. The coated glass substrate is then sprayed with a liquid cadmium chloride solution using an ultrasonic spray machine. The sprayed coated glass substrate is then baked to form an activated CdTe coated glass substate. Alternatively, the chloride activation process may use a heat treatment in partial pressure vapors of cadmium chloride in air or nitrogen or helium. Alternatively, magnesium chloride may be used in place of cadmium chloride. Alternatively, the cadmium chloride or magnesium chloride may be applied to the coated glass using alternative application methods other than spraying, that may include, but are not limited to, roll coating or spin coating.

The activated coated glass substate is then ablated to form a plurality of P1 laser scribes (or isolation scribes), which dictate how the electrons will flow through the CdTe coated glass substrate and to the connecting buss tape, which is applied later in the process. Each P1 scribe is a 10-50 micron wide scribe that ablates through all material to the glass layer 14, as shown in FIG. 3. The P1 scribes may be used to create about 156 cells (about 78 cells in each half submodule for low voltage modules) to about 117 cells (for high voltage modules) in a 2 foot by 4 foot module. Negative photoresist material (NPR), a UV crosslinking polymer, may be used to fill and insulate the P1 scribes. The NPR may be rolled on to the CdTe coated glass substrate, allowing it to fill the voids left by the P1 scribes. The NPR is then baked to remove excess moisture and exposed to UV light from the uncoated side of the glass layer 14. Alternatively, the P1 scribes may be backfilled and cured with another insulating material that is compatible with subsequent processing steps.

The CdTe coated glass substate is then ablated again to form a plurality of P2 laser scribes, each spaced 10-50 microns away from each of the P1 scribes. Each P2 scribe ablates all of the coating materials except for the TCO layer 16. Once filled with a metal or other conducting material, as described below, this scribe will serve as the bridge between the two conductive surfaces, the TCO layer 16 and the conductive back contact layer 20.

The CdTe surface may be treated, prior to the application of a conductive back contact 20 by applying a liquid solution of copper chloride or vacuum deposition of copper (such as by evaporation or sputtering). After a heat treatment, the CdTe surface becomes doped p-type to facilitate the transport of electrical current out of the CdTe and into the back contact layer 20. Copper is a typical dopant for this back contact layer 20 and it may be provided also by a copper-doped zinc telluride layer. Alternative p-type dopants for CdTe may include arsenic, phosphorus, or antimony.

In one embodiment, the conductive back contact layer 20 may include, but not limited to, three metals, all of which are applied through the process of sputtering or metallization. In a first embodiment, the first metal is molybdenum, followed by aluminum, and finally chromium or other non-oxidizing metal. In a second embodiment, the first layer is molybdenum nitride, followed by aluminum, and finally chromium. The metals fill the P2 scribes and connect the metal back contact layer 20 to the TCO layer 16.

A plurality of P3 scribes are then ablated through the conductive back contact layer 20 and are disposed 10-50 microns away from each respective P2 scribe. The P3 scribe or the rear cell isolation scribe, is the last cell scribe needed to allow the scribed cells to work in series, allowing the electrons to flow from cell to cell on the submodule.

Once the thin film submodule 12 has been created, it is subjected to a laser edge deletion (LED) process, whereby all of the layers of coating material around the perimeter of the submodule 12 is removed, exposing the glass. In one embodiment, a perimeter of at least 10 mm is created to provide an electrically insulating border between the electrical generating surface and the submodule's most outer edge.

Once the border is created, the submodule undergoes an annealing process and a conductive buss tape 22 is adhered to the submodule 12. The buss tape configuration collects the electrons from the scribed cells and terminates to the junction box wires 24, as described below.

As shown in FIGS. 1 and 2, the enameled steel-backed thin film module 10 is created by applying a polyisobutylene (PIB) edge seal (about 0.7 mm to about 8 mm wide) to the perimeter surface that was ablated by the LED machine, which will act as a seal between the submodule and the back steel layer 28. The PIB creates a hermetic seal that keeps the elements away from the semiconductor material. Next, a lamination material layer (or “interlayer) 26 (e.g., any ionomer or polyolefin, including but not limited to PVB (polyvinylbutyral) or TPU (a thermo-plastic polyurethane)) is applied on top of the PIB border, and an enameled steel layer 28 is applied on top of the lamination layer 26.

As shown in FIG. 2, the enameled steel layer 28 includes a steel core 30, which may be made of 20-30 Gauge steel. In one embodiment, the steel core 30 may be powder coated or roll coated with a glass powder enamel coating using a water slurry drip, an electrostatic powder coating sprayer, or other suitable application techniques. Once the enamel material is applied to the steel core 30, the layer 28 is heat treated at approximately 590 to 925*C, which fuses the coating into a continuous glassy coating on the steel core 30. In one embodiment, the glass powder enamel material includes ground glass powder “frits” that are selected to match the thermal expansion of the steel core 30.

In one embodiment, the coating may include an inner enamel-ground coat 32 fused to both the laminating surface and the outer surface of the steel core 30. The enamel-ground coat 32 is designed to provide a very adherent layer chemically bonded with the steel surfaces during high temperature heat treatment. The layer may also include an enamel-cover coat 34 disposed on either or both exposed surfaces of the enamel-ground coat 32 layer. The enamel-cover coat 34 provides a smooth outer glassy enamel layer that has the designed physical properties required for the application. As shown in FIG. 2, the steel layer 28 may be about 0.4 to about 0.6 mm thick, with an enamel thickness of about 0.05 mm to about 0.5 mm on each side of the steel core 30. In one embodiment, the enamel thickness is about 0.15 mm on each side of the steel core 30. It is important to note that any exposed steel surfaces may be covered with a non-conductive material, such as the enameling material, to prevent unwanted electrical conductivity and wear of the module. Alternatively, the enameled steel may be replaced with a polymer sheet, a ceramic sheet, or other suitable electrically insulative backing material.

It should be understood that the insulative backsheet materials can be molded as individual sheets or roll to roll manufactured. The thickness of any coating will be determined based on the dielectric strength of the coating material. For example, in one embodiment of the steel enameled backsheet, the coating was about 0.15 mm to about 0.5 mm thick for a 0.72 m² thin film PV module. The 0.15 mm steel enameled embodiment exhibited sufficient dielectric strength for a thin film PV module for use in a building material, pursuant to IEC and UL 61215-1 safety testing standards.

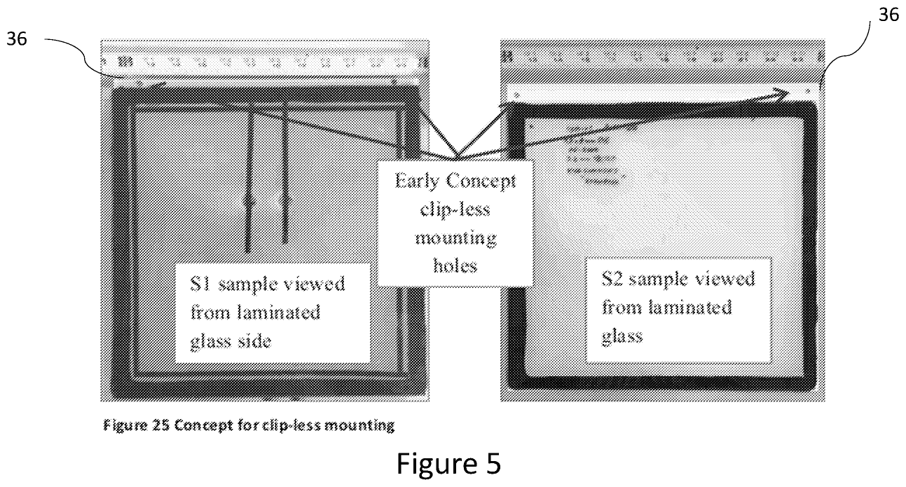

In one embodiment, the enameled steel layer 28 may also include a clip-less mounting feature 36, as shown in FIG. 5. In this embodiment, two holes are disposed through a portion of the enameled steel layer 28 that extends above the height of the submodule 12, forming the clip-less mounting features 36. The features 36 may be used to accommodate module fasteners (not shown).

The through holes allow a screw or bolt to pass through the module and connect to a racking mounting structure under the module. The racking mounting structures are generally universal and only require a bolt attachment to connect the module to the racking frame. Typical bolt sizes to connect a module to a racking frame include ¼-20 or m6 bolt sizes. This feature eliminates the extra clamp or clip typically required for the ¼ or 6 mm bolt to connect to the racking.

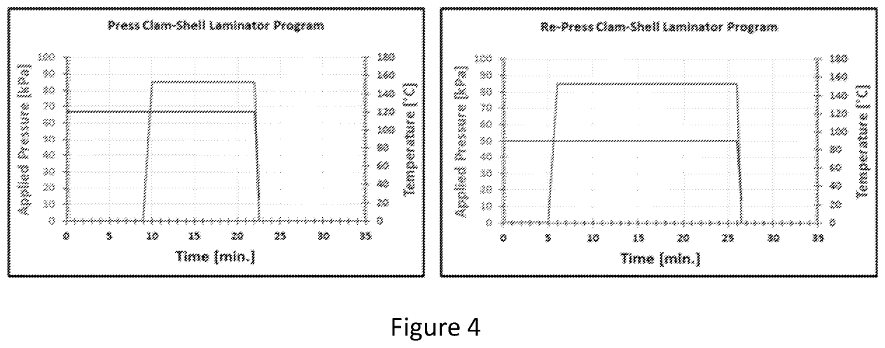

The completed module stack is then passed through a lamination machine to evacuate any trapped air between the submodule 12 and the enameled steel layer 28. A hot press is then applied to squeeze the submodule 12 and the enameled steel layer 28 together as it heats, melting the lamination layer 26 and the PIB. In one embodiment, a Press plus Re-press lamination process is used, as illustrated in FIG. 4. During the first pressing step, the completed module stack is pressed at 120° C. with 85 kPa of pressure for at least 12 minutes. In the second Re-press step, the stack is pressed at 90° C. with 85 kPa of pressure for 20 minutes. This two-step pressing process produces a substantially flat completed module. It should be understood that any pressing process that allows the submodule 12, lamination layer 26, and enameled steel layer 28 to adhere evenly, without unwanted bowing, would be acceptable. The last step is a cool-down while squeezing the laminated module 10 and controlling cooling to create the final product.

As shown in Table 1, varying combinations of steel thickness (by Gauge #) and enamel thicknesses (in μm and mm), along with their corresponding steel weights and two-sided enamel weights (in kg), were calculated for examples of thin film PV modules with an area of 0.72 m². The samples were then tested to determine if the required safety standards were met.

TABLE 1

| | | Enamel | Gauge # | | | | | | | | | |
|---|---|---|---|---|---|---|---|---|---|---|---|---|
| | | two | 19 | 20 | 21 | 22 | 23 | 24 | 25 | 26 | 28 | 30 |
| Enamel | Enamel | side | Steel weight, kg | | | | | | | | | |
| Thickness, | Thickness, | weight, | 5.995 | 5.149 | 4.718 | 4.288 | 3.858 | 3.427 | 2.997 | 2.567 | 2.137 | 1.721 |
| μm | mm | kg | Weight, kg - 2x enameled steel | | | | | | | | | |
| 50 | 0.05 | 0.180 | 6.175 | 5.329 | 4.898 | 4.468 | 4.038 | 3.607 | 3.177 | 2.747 | 2.317 | 1.901 |
| 100 | 0.1 | 0.360 | 6.355 | 5.509 | 5.078 | 4.648 | 4.218 | 3.787 | 3.357 | 2.927 | 2.497 | 2.081 |
| 150 | 0.15 | 0.540 | 6.535 | 5.589 | 5.258 | 4.828 | 4.398 | 3.967 | 3.537 | 3.107 | 2.677 | 2.261 |
| 200 | 0.2 | 0.720 | 6.715 | 5.869 | 5.438 | 5.008 | 4.578 | 4.147 | 3.717 | 3.287 | 2.857 | 2.441 |
| 250 | 0.25 | 0.900 | 6.895 | 6.049 | 5.618 | 5.188 | 4.758 | 4.327 | 3.897 | 3.467 | 3.037 | 2.621 |
| 300 | 0.3 | 1.080 | 7.075 | 6.229 | 5.798 | 5.368 | 4.938 | 4.507 | 4.077 | 3.647 | 3.217 | 2.801 |
| 350 | 0.35 | 1.260 | 7.255 | 6.409 | 5.978 | 5.548 | 5.118 | 4.687 | 4.257 | 3.827 | 3.397 | 2.981 |
| 400 | 0.4 | 1.440 | 7.435 | 6.589 | 6.158 | 5.728 | 5.298 | 4.687 | 4.437 | 4.007 | 3.577 | 3.161 |
| 450 | 0.45 | 1.620 | 7.615 | 6.769 | 6.338 | 5.908 | 5.478 | 5.047 | 4.617 | 4.187 | 3.757 | 3.341 |
| 500 | 0.5 | 1.800 | 7.795 | 6.949 | 6.518 | 6.088 | 5.658 | 5.227 | 4.797 | 4.367 | 3.937 | 3.521 |

The areas in bold are the weights of the sample enameled steel backing sheets that 1) are less than that of current soda lime or borasilicate glass backsheets for known PV modules. i.e. less than 5.76 kg for a 3.2 mm thick glass, and 2) would pass the IEC and UL safety standard 61215-1, i.e. samples having an enamel thickness of at least 0.15 mm. Therefore, suitable example combinations of steel thickness and enamel weight and thickness for the thin film PV module may be determined. Similar calculations may be made for alternative insulative materials. Information on the range of dielectric breakdown strengths for various types of enamels, materials, and coatings, may be obtained from the Porcelain Enamel Institute, Inc. (PEI). It was found that to achieve sufficient dielectric breakdown strength for the enameled steel backsheet, “high” dielectric breakdown strength enamels are required, such as porcelain enamel. Typically, a “high” dielectric breakdown strength is considered to be at or above 25.6 V/μm.

The thickness of the thin film module 10 may be from about 2 μm to about 2 inches. It should be understood that the thickness and the weight of the module 10 will be determined by the application for which it is used. For Example, for rooftop applications, the weight of the module 10 is based on the structural assessment of the roof for additional deadload limits. For a ground mount, the weight limit is determined by the limits of the racking or mounting structure.

Although the description has been focused on the use of the photovoltaic module in a roofing or building façade application, it should be understood that this module may have many more applications, such for use in cars, buses, trucks, etc. (i.e. roof coverings or sunroof materials), unmanned aerial vehicles, boats, and for general space applications.

This written description sets forth the best mode of carrying out the invention, and describes the invention so as to enable a person of ordinary skill in the art to make and use the invention, by presenting examples of the elements recited in the claims. The detailed descriptions of those elements do not impose limitations that are not recited in the claims, either literally or under the doctrine of equivalents.

1. A thin film photovoltaic module comprising:
a submodule comprising a first glass layer, a transparent conducting oxide layer, a thin film semiconductor layer, and a conductive back contact layer;
a lamination layer; and
an electrically insulative backing layer.

2. The module of claim 1, wherein the electrically insulative backing layer comprises enameled steel, a polymer material, a ceramic material, or a combination thereof.

3. The module of claim 1, wherein the electrically insulative backing layer comprises a steel core having a first side and a second side, wherein the first and second sides are coated with a glass powder enamel material.

4. The module of claim 3, wherein the glass powder enamel material is at least about 0.15 mm thick on each of the first and second sides of the steel core.

5. The module of claim 1, wherein the thin film semiconductor layer comprises cadmium telluride, copper indium gallium selenium, amorphous silicon, perovskites, or combinations thereof.

6. The module of claim 5, wherein the semiconductor layer is no more than 10,000 nm thick.

7. The module of claim 1, wherein the lamination layer includes a polyolefin material.

8. The module of claim 1, wherein the electrically insulative backing layer includes a clip-less mounting feature defined by at least a first hole and second hole formed through the electrically insulative backing layer.

9. A method of making a thin film photovoltaic module, the method comprising:
providing a submodule comprising a first glass layer, a transparent conducting oxide layer, a thin film semiconductor layer, and a metal back contact layer; and
applying a lamination layer and an electrically insulative backing layer on top of the conductive back contact layer.

10. The method of claim 9, wherein the electrically insulative backing layer comprises enameled steel, polymer material, ceramic material, or a combination thereof.

11. The method of claim 9, wherein the electrically insulative backing layer comprises a steel core having a first side and a second side, and wherein the first and second sides are coated with a glass powder enamel material.

12. The method of claim 11, wherein the glass powder enamel material is applied to each of the first and second sides of the steel core in a layer having a thickness of at least about 0.15 mm.

13. The method of claim 9, wherein the thin film semiconductor layer comprises cadmium telluride, copper indium gallium selenium, amorphous silicon, perovskites, or combinations thereof.

14. The method of claim 9, wherein the semiconductor layer is no more than 10,000 nm thick.

15. The method of claim 9, wherein the application of the lamination layer and the electrically insulative backing layer to the submodule includes a two-step pressing process.

16. The method of claim 9, wherein the lamination layer includes a polyolefin material.

17. The method of claim 9, wherein the method further includes forming at least a first and second mounting hole within the electrically insulative backing layer.
